(19) United States
(12) Patent Application Publication
(10) Pub. No.: US 2015/0001736 A1
(43) Pub. Date: Jan. 1, 2015

(54) DIE CONNECTIONS USING DIFFERENT UNDERFILL TYPES FOR DIFFERENT REGIONS

(71) Applicants: Hualiang Shi, Chandler, AZ (US); Shengquan Ou, Chandler, AZ (US); Sairam Agraharam, Chandler, AZ (US); Shan Zhong, Chandler, AZ (US); Sivakumar Nagarajan, Chandler, AZ (US); Weihua Tang, Chandler, AZ (US)

(72) Inventors: Hualiang Shi, Chandler, AZ (US); Shengquan Ou, Chandler, AZ (US); Sairam Agraharam, Chandler, AZ (US); Shan Zhong, Chandler, AZ (US); Sivakumar Nagarajan, Chandler, AZ (US); Weihua Tang, Chandler, AZ (US)

(21) Appl. No.: 13/931,909

(22) Filed: Jun. 29, 2013

(51) Int. Cl. H01L 21/762; H01L 25/065

(52) U.S. Cl. CPC H01L 21/76251; H01L 25/0657
USPC 257/777; 438/455

(57) ABSTRACT

Die connections are described using different underfill types for different regions. In one example, a first electrically-non-conductive underfill paste (NCP) type is applied to an I/O region of a first die. A second NCP type is applied outside the I/O region of the first die, the second NCP type having more filler than the first NCP type, and the second die is bonded to a first die using the NCP.

### FIELD

The present disclosure relates to the field of solder flux and underfill and, in particular, to using different underfill formulations for different areas in connecting dies.

### BACKGROUND

Semiconductors and micromechanical dies are typically packaged for protection and to be connected with other components, such as a logic board or other substrate. Within the package, a die can be electrically connected to other dies or to a package substrate or both. The connections are made using pins, lands, a ball grid, or another array of connectors on the die that are soldered to a corresponding array on the other die, on the package substrate or on some other connection or routing surface. The solder connections are made by applying solder to all of the connection points and then placing the two parts into a reflow oven to melt the solder and electrically connect all of the connection points. Flux is used with the solder to wet the surfaces and allow the solder to make a better electrical connection on both sides.

Electrically-non-conductive underfill paste (NCP) is applied with thermal compression bonding for 3-D packages, among others. A 3-D package features two dies stacked on each other and connected to a package substrate for connection to a PCB (Printed Circuit Board). The NCP is dispensed onto the surface of the first die, then the second die is bonded to the first die using heat and pressure. The NCP is complex and has different components, including resins (such as epoxy bisphenol, acrylates, hybrid resins), hardeners (such as acid anhydride, amine), fillers (thermally-conductive or thermally-non-conductive, such as silica), fluxing agents (such as carboxylic acids, acid anhydride), etc..

The size and loading percentage of the fillers in electrically-non-conductive underfill paste (NCP) are usually tuned to modify the material properties, such as the modulus, CTE (Coefficient of Thermal Expansion), viscosity, etc. The material properties of electrically-non-conductive underfill paste (NCP) are also optimized to match the curing profile of NCP with the reflow profile of solder. The profiles can include such properties as a low viscosity before solder reflow and a rapid viscosity increase after solder reflow.

By applying the electrically-non-conductive underfill paste (NCP) with thermal compression bonding, the assembly process is simplified. Flux dispensing, deflux, underfill capillary flow and oven curing are eliminated. The thermal compression bonding process combines solder reflow and underfill curing into one step, reducing capital investment and total cost and time for the process.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a cross-sectional diagram of a single I/O solder connection after thermal compression bonding.

FIG. 2A is a cross-sectional diagram of a solder bump on an I/O pad of a die.

FIG. 2B is a perspective view diagram of a portion of a connection area of a die after the solder bumps have been flattened.

FIG. 3A is a top elevation view diagram of a portion of an interconnection area of a die according to an embodiment.

FIG. 3B is a side cross-sectional view diagram of the die of FIG. 3A according to an embodiment.

FIG. 4A is a top elevation view diagram of a portion of the die of FIG. 3A with NCP applied according to an embodiment.

FIG. 4B is a side cross-sectional view diagram of a portion of the die of FIG. 4A according to an embodiment.

FIG. 4C is top elevation view diagram of a portion of an interconnection area of an alternate die with NCP applied according to an embodiment.

FIG. 4D is side cross-sectional view diagram of a portion of the die of FIG. 4C according to an embodiment.

FIG. 5A is a top elevation view of a portion of the die of FIG. 3A with NCP distributed across the die according to an embodiment.

FIG. 5B is a side cross-sectional view of a portion of the die of FIG. 5A with a second die attached according to an embodiment.

FIG. 6A is a top elevation view diagram of a portion of an interconnection area of a die with an NCP preform applied according to an embodiment.

FIG. 6B is a side cross-sectional view diagram of a portion of the die of FIG. 6A according to an embodiment.

FIG. 6C is a side cross-sectional view diagram of a portion of the die of FIG. 6A with a second die attached according to an embodiment.

FIG. 6D a top elevation view diagram of a portion of an interconnection area of an alternate die with an NCP preform applied according to an embodiment.

FIG. 6E is a side cross-sectional view diagram of a portion of the die of FIG. 6D with a second die attached according to an embodiment.

FIG. 7A is a simplified cross-sectional diagram of a stacked die package according to an embodiment.

FIG. 7B is a simplified cross-sectional diagram of a single die package according to an embodiment.

FIG. 8 is a block diagram of a computing device incorporating an underfilled semiconductor die according to an embodiment of the invention.

### DETAILED DESCRIPTION

Wide I/O is a new standard from JEDEC for connection of a memory die to a processor die using through-silicon vias (TSV) and a 3D package. The Wide I/O DRAM (Dynamic Random Access Memory) standard specifies 4 128-bit channels, providing a 512-bit interface to DRAM. Future wide I/O standards will provide faster data rates and may boost bandwidth to as high as 2 Terabits/second. The present description refers to larger pads as Wide I/O, however, the same principles may be applied to any pad large enough to benefit from the principles described herein. There is no requirement that the pad connect to DRAM, support any particular protocol or clock frequency, nor comply with any particular standard. In addition, while 3-D packaging is discussed herein, the same principles may be applied to any stacked die combination and any die package combination that uses an underfill paste, whether packaged or unpackaged.

In a 3-D package that includes I/O pads including Wide I/O, electrically-non-conductive underfill paste (NCP) can be dispensed onto the surface of the first die prior to attaching the second die with thermal compression bonding. The NCP may be optimized to match the curing profile of NCP with the reflow profile of solder.

The NCP can have flux or no flux, depending on the I/O pad surface finish, for example gold, and the conditions of Thermal Compression Bonding (TCB), for example force. In a fluxing version of NCP, the fluxing agent can reduce the metal oxides, such as tin oxide and copper oxide, that have formed on a metal connection. This allows wetting of the solder on the oxidized metal pads and improves joint formation. In a fluxless version of NCP, the TCB force can be used to break down the tin oxide on a metal pad and allows a solder joint to be formed.

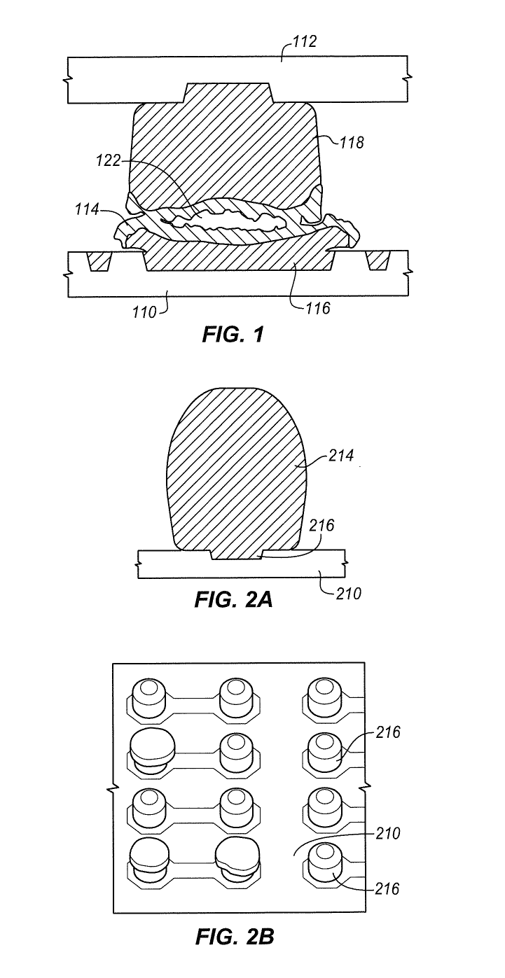

FIG. 1 is a cross-sectional diagram of a single I/O solder connection after thermal compression bonding. A first die 110 has been connected to a second die 112 by a solder joint 114. The connection is between a first I/O pad 116 on the first die and a second I/O pad 118 on the second die. As a result, fillers 122 from the electrically-non-conductive underfill paste (NCP) are entrapped inside the solder joint between the two I/O pads from the two dies. The two pads were soldered together with NCP applied to one of the dies and solder applied to the pad on one or both of the dies. During thermal compression bonding, the NCP mixed with the solder and fillers in the NCP became trapped in the solder joint.

The filler, for example silica or another material, is not electrically conductive. As a result, it can cause failures, performance degradation, and reliability risks for the final packaged product. The entrapped filler can also affect the electric performance and the thermal mechanical reliability of the resulting device. Electrically, the filler is dielectric and can create a capacitive delay of signals through the pads. It can also increase power consumption and reduce the maximum current that can flow through the connection. The mechanical failures can come from a crack or other mechanical failure.

By using two different NCP formulations, one for inside an I/O region, the other for outside the I/O region, performance is improved. The risk of filler entrapment is reduced for the application of NCP with thermal compression bonding in, for example, a 3-D package with Wide I/O. However, the techniques described herein may be applied to other types of packages and solder connections.

Filler entrapment is a complex phenomenon that is influenced by many different factors. Filler entrapment may be a function how well the solder bumps are aligned horizontally and vertically on the surface of the die. It may be a function of the geometry of the I/O pads on the die. It may be a function of the material properties of the NCP and of the conditions of the thermal compression bonding.

The coplanarity of the solder bumps can be improved using a higher bonding force. This also improves the quality of the thermal compression bonding. However, filler may still be trapped within the solder joints. FIG. 2A is a cross-sectional diagram of a solder bump 214 on an I/O pad 216 of a die 210. When the solder bump is applied, it has a tall and rounded shape. The shape of each solder bump varies across the die.

FIG. 2B is a perspective view diagram of a portion of a connection area of the die 210 after the solder bumps have been flattened. The bumps may be flattened by pressing the solder bumps against a flat surface during die pick-up or attachment. After the compression, the solder bumps are all shorter and closer to the same height. The tops of the solder bumps are flattened to varying degrees as shown in the diagram. The amount of flattening will depend on the shape of the solder ball before the compression was applied. Because filler is much harder than solder, especially at high temperatures, filler might induce indentation effects and get embedded inside the solder bump during the solder bump flattening process. However, once the filler gets embedded inside the solder, it cannot be easily pushed out when the solder is melted during the solder reflow process.

The possibility of trapped filler can be avoided by using less or no filler. In other words, the filler entrapment can be avoided with unfilled (zero filler loading) NCP. In, for example, a 3-D package, the NCP material may be designed to have good material resistance to cohesive fracture and interfacial delamination. Unfilled NCP usually has a high CTE and low modulus, which reduces its mechanical reliability through temperature changes.

Two types of NCP may be applied to different places on the same die for a hybrid application. This can be done in different ways that alleviate the risk of filler entrapment. The techniques described herein are particularly suitable for the application of NCP with TCB in a 3-D package with Wide I/O, however the invention is not so limited.

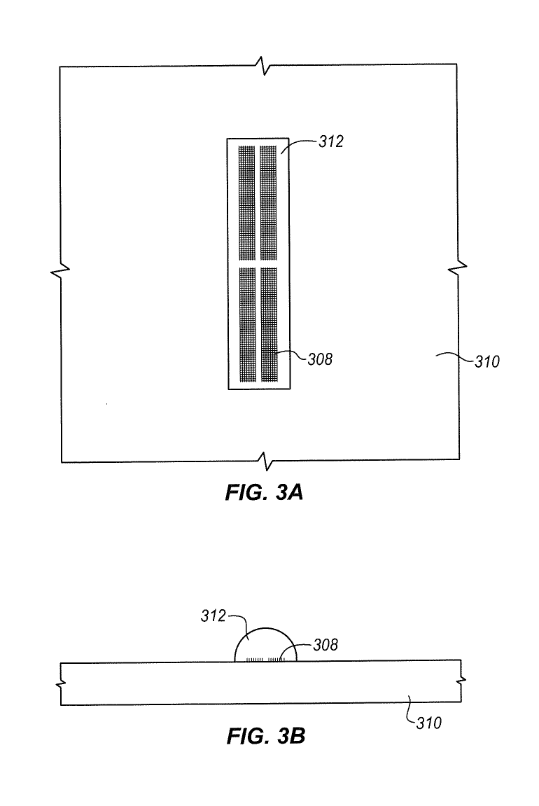

In the example of FIGS. 3A and 3B, the I/O regions are covered by unfilled NCP, that has zero filler loading. The area outside the I/O region is covered by a filled NCP. Typical nonconductive paste formulations (type 1 and 2) are shown in the Table below. Because the NCP inside the I/O regions has zero filler loading, there will be no filler entrapment inside the I/O solder joint. The filled NCP and unfilled NCP can have the same type of chemistry or different types of chemistry (such as anhydride-based for unfilled NCP within the I/O region and amine-based for filled NCP outside the I/O region). Different chemistries have different advantages, for example amine has better moisture resistance and adhesion while anhydride has better fluxing capability.

While in the example of the Table, the Type 1 NCP has no fillers, it may have a small amount of filler. The precise amount of filler may be determined empirically, however, the fillers are not needed when the I/O region is small compared to the total surface of the die. The Type 2 NCP has about 75% filler, however, this amount may be modified to suit different applications. For stacking DRAM on a processor in a 3D stacked die, 65% and 75% filler both show the desired mechanical and thermal properties. While silica is shown as the filler, other fillers may be used. Similarly the other components of the Table may be replaced with other similar materials.

TABLE

| Formulation | | |
|---|---|---|
| Components | NCP Type-1 | NCP Type 2 |
| Resin | Bisphenol epoxy, high molecular weight | |
| | and/or multifunctional epoxies, or acrylates | |
| Curing Agent | Acid anhydride | Amine or Acid |
| | | anhydride or Free |
| | | radical cure agents |
| Fluxing agent | Carboxylic acids, Acid anhydrides | |
| Fillers | None | Silica |
| Other Additives(Adhesion | Yes | Yes |
| promoters etc.,) | | |

FIG. 3A is a simplified top elevation view diagram of a portion of an interconnection area 308 of a die 310. In this and the other diagrams, the I/O regions may take different forms that may be much more complex than that illustrated. The configuration and overall shape of the I/O pads may be adapted to suit a variety of different applications. The I/O is covered by a first type of NCP 312 that is formulated for use on the I/O areas. This first type of NCP has zero filler and may also be specifically formulated in other ways. FIG. 3B is a side cross-sectional view diagram of the same portion of the die 310 showing that, in this example, the I/O regions 308 are covered by first type of NCP.

Usually, NCP with zero filler loading has a high CTE and a low modulus. This tends to reduce the thermal mechanical reliability of any joints formed. Fillers are usually added specifically to address this concern. However, because the I/O region is very small compared to the total area of the die and because the NCP outside the I/O region has a high filler loading, the thermal mechanical properties of the joint outside the I/O region is not impacted.

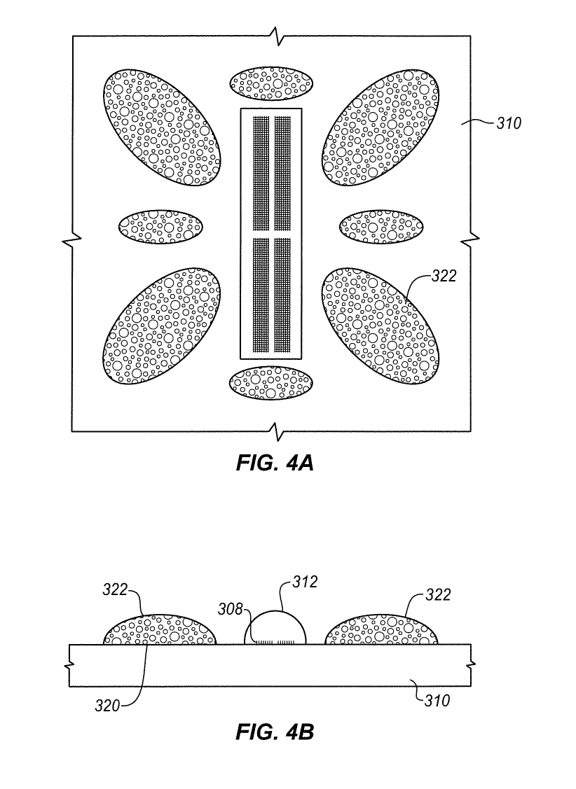

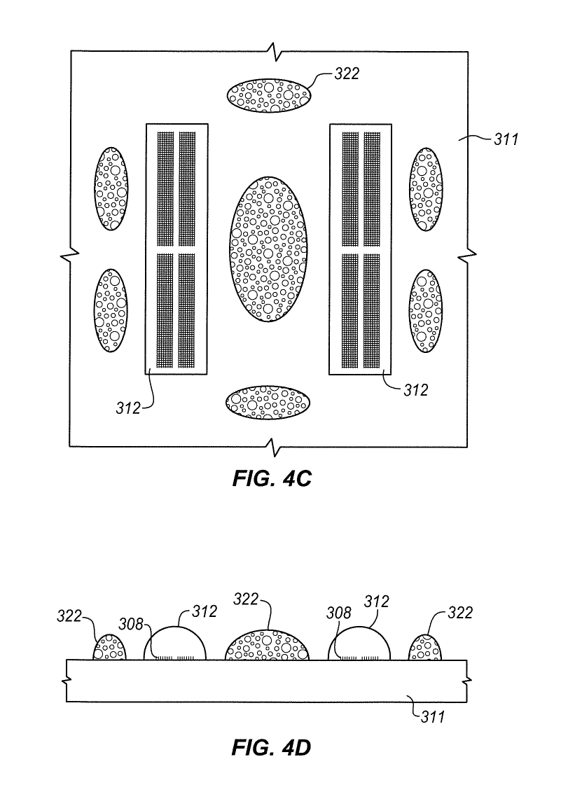

As shown in FIG. 3A, a first type of NCP is dispensed over the top of the die 310 to cover only the I/O regions 308 on the die. Then as shown in FIG. 4A, a diagram of a top elevation view of the same die, a certain amount of a second type of NCP 322 with some filler, for example a high filler loading of about 75%, is dispensed outside the I/O regions. As suggested by the diagram, the regions outside the I/O regions are significantly larger so that the second type of NCP is used much more than the first type of NCP. FIG. 4B is a diagram of a side cross-sectional view of the same die as in FIG. 4A showing both types of NCP (312, 322).

While the example of FIGS. 4A and 4B show a die with a central I/O area 308, the same principles may be applied to dies with different arrangements of I/O regions. FIG. 4C is an example of a die 311 with peripheral I/O 308 and a central region with no I/O. The same two types of NCP (312, 322) are used so that the filled NCP is used in the central region and the unfilled NCP is used in the peripheral areas of the I/O regions. FIG. 4D is a side cross-sectional view of the same die 311 with peripheral I/O and an open central area. The configuration of the I/O area is provided as an example and may be different and much more complex than that shown.

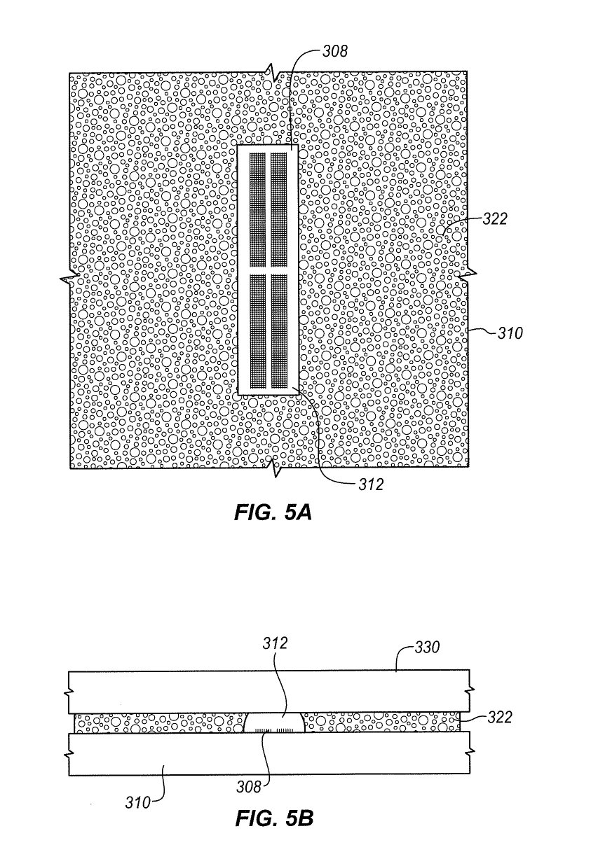

After the NCP is dispensed on the die, a second die 330 is then attached to the first die 310 using thermal compression bonding or another appropriate technique. Typically, solder balls, caps, or contacts (not shown) are applied to the pads of one or both of the dies before the NCP is dispensed over one of the dies. FIG. 5A shows a top elevation view of the distribution of the NCP layer between a first 310 and second 330 die. This top elevation view shows that there is much more area covered with the second, filled type of NCP 322 than is covered with the first, unfilled type of NCP 312. FIG. 5B shows a cross-sectional side view diagram so that the first 310 and second 330 stacked dies can be seen.

In order to reduce voiding of the NCP, the dispense process (patterns, shot weights, etc.), material property (viscosity, surface tension, etc.), and thermal compression bonding process (force, speed, temperature, etc.) may be modified to suit any particular implementation, die type, or design objective. The two types of NCP may be dispensed from different jets at the same time or a single jet may be used by changing the NCP that is supplied to the jet during use.

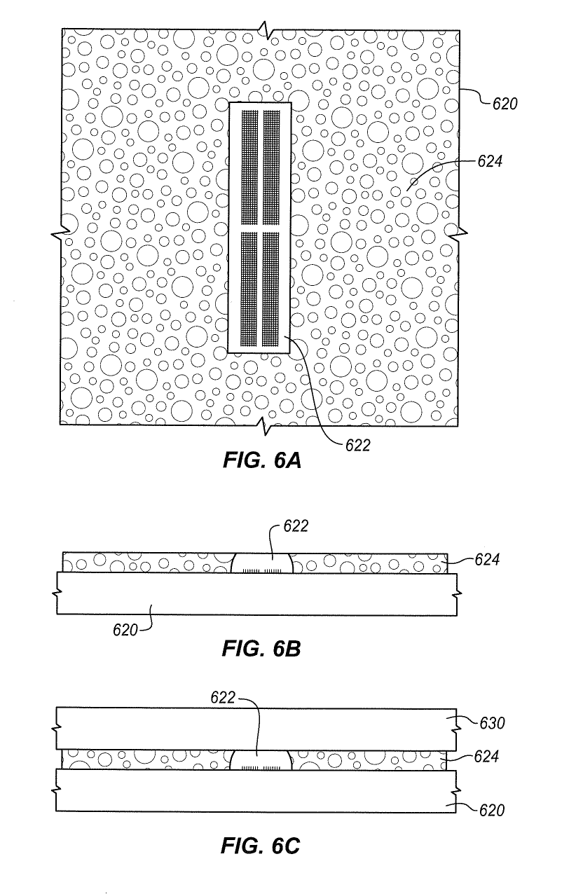

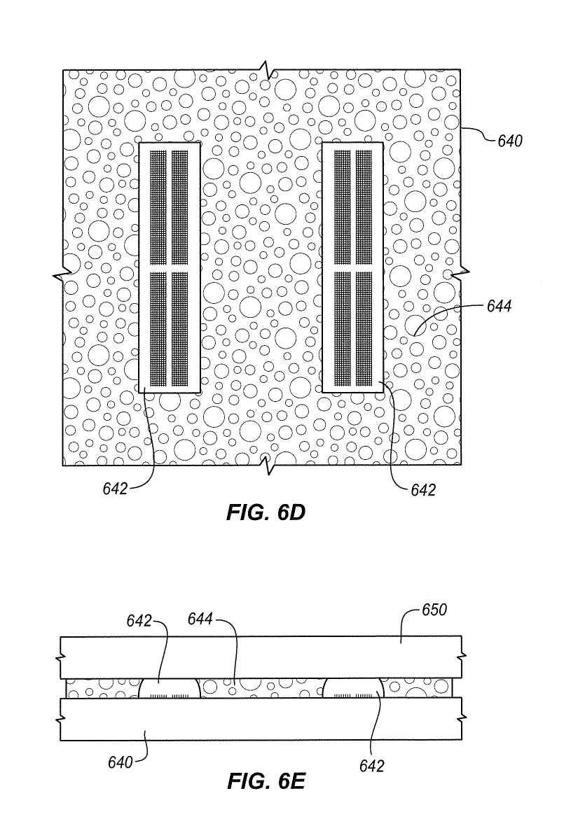

Alternatively, the two different types of NCP can be applied using a preform. A preform film as shown in the top elevation diagram of FIG. 6A is created that has unfilled NCP 622 in the I/O region, and filled NCP 624 outside the I/O region. The preform is placed at the top of a first die 620 as shown in the side cross-sectional view FIG. 6B. FIG. 6B shows the same preform and I/O regions as FIG. 6A.

As shown in the cross-sectional side view of FIG. 6C, a second die 630 is then attached to the first die 620 through the preform using, for example, thermal compression bonding. The preform melts to enable solder joint formation between the first and second dies. The hybrid NCP dispensing reduces surface oxidation on the two metallized surfaces.

FIG. 6D shows an alternative die 640 with peripheral I/O regions and a central open area. As in the example of FIG. 6A, a perform film with peripheral unfilled NCP regions 642 and central filled NCP regions 644 is placed over the first die 640. The second die 650 is compression bonded using, for example, TCB to the first die to form the die stack of FIG. 6E with peripheral I/O.

The two techniques for using two different types of NCP on one die surface reduce capital investment, cost, and process time. No additional tools, materials, processes, such as photoresist spin-coating, photo lithography, development, solder electroplating or solder ball print, solder reflow, and photoresist stripping are required.

The two techniques may be applied to a wide variety of different package types. It may be used when bonding two dies to each other or when bonding a die to a package substrate or for other bonding situations. For Wide I/O, the techniques may be applied to bonding a microprocessor to DRAM. However, they may be applied as well to bonding other types of memory or processors to a microprocessor or other type of processor or to bonding two memory dies together.

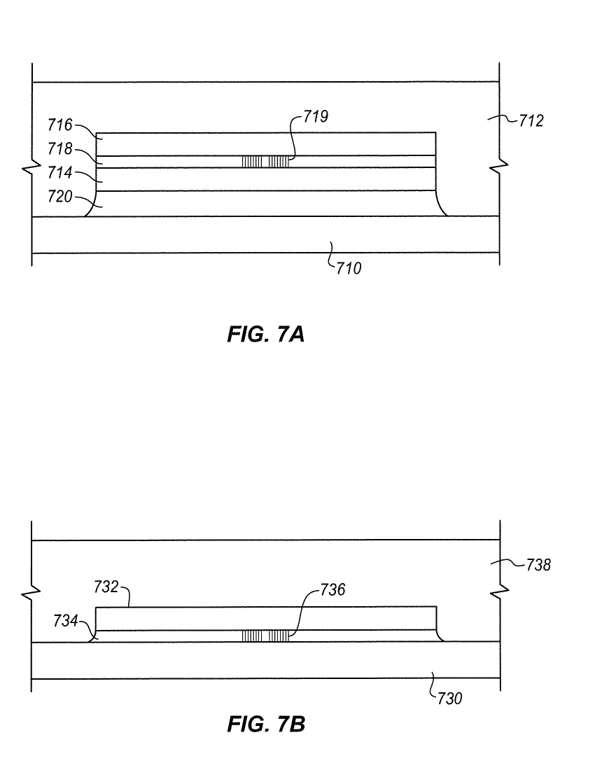

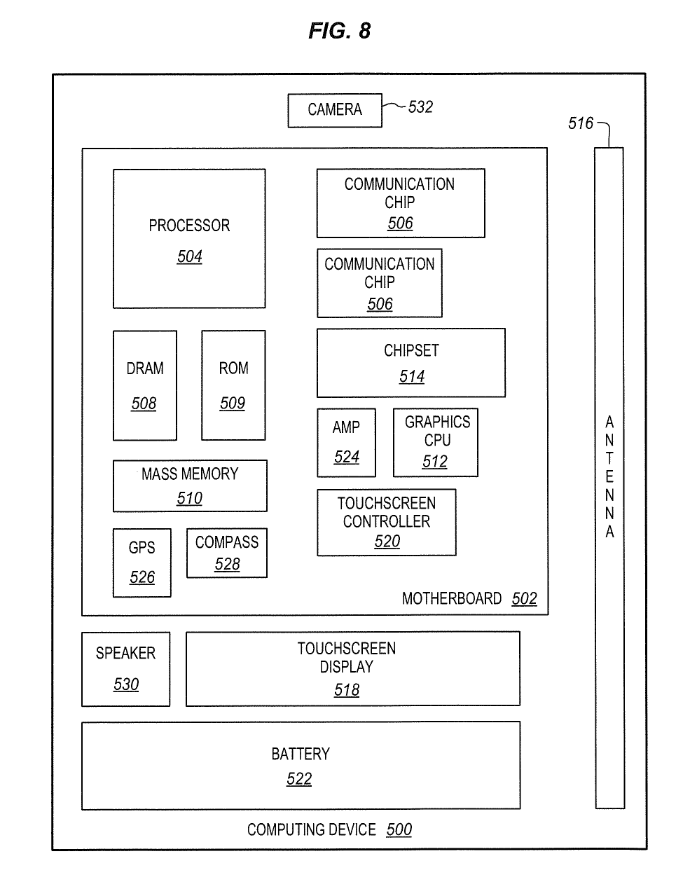

FIG. 7A is a simplified cross-sectional diagram of a stacked die package suitable for the hybrid NCP techniques described herein. The package substrate 710 supports two stacked dies 714, 716. The dies are bonded together by NCP in an underfill layer 718. The electrical contacts are joined with solder 719 as described in more detail herein. The bottom die 714 is also bonded to the package substrate 710 by underfill 720. There may or may not be solder or other types of electrical connections. Alternatively, there may be wire bond, vias, or other or additional types of connections between the dies and package 710. A molding compound 712 covers the package and isolates the dies.

FIG. 7B is a simplified cross-sectional diagram of a single die package suitable for the hybrid NCP techniques described herein. The die 732 is attached to the package substrate 730 using hybrid underfill 734 such as the two types of NCP described herein. The I/O area 736 is soldered together to make electrical connections to the package substrate. The package 730 and the die are covered with a mold 738 as in the example of FIG. 7A. In both cases, a cover, shield, or other protective device may be used instead of the molding compound shown.

FIG. 8 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM) 508, non-volatile memory (e.g., ROM) 509, flash memory (not shown), a graphics processor 512, a digital signal processor (not shown), a crypto processor (not shown), a chipset 514, an antenna 516, a display 518 such as a touchscreen display, a touchscreen controller 520, a battery 522, an audio codec (not shown), a video codec (not shown), a power amplifier 524, a global positioning system (GPS) device 526, a compass 528, an accelerometer (not shown), a gyroscope (not shown), a speaker 530, a camera 532, and a mass storage device (such as hard disk drive) 510, compact disk (CD) (not shown), digital versatile disk (DVD) (not shown), and so forth). These components may be connected to the system board 502, mounted to the system board, or combined with any of the other components.

The communication chip 506 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor, memory devices, communication devices, or other components include one or more dies that are packaged together using a hybrid NCP, if desired. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a method for connecting dies with electrically-non-conductive underfill paste (NCP), the method including applying a first electrically-non-conductive underfill paste (NCP) type to an I/O region of a first die, applying a second NCP type outside the I/O region of the first die, the second NCP type having more filler than the first NCP type, and bonding the second die to a first die using the NCP.

In further embodiments, applying the first and the second NCP types comprises applying using a dispenser, applying the first and the second NCP types comprises placing a preform film including the first and second NCP types on the first die, applying the first NCP type comprises covering the I/O region with an NCP with zero filler loading, applying the second NCP type comprises covering an area outside the I/O region with a filled NCP, and the second type of NCP has a filler loading.

Further embodiments include forming a preform film with unfilled NCP in an area corresponding to the I/O region and filled NCP in an area outside the I/O region and applying the first and the second NCP type comprises placing the preform film at the top of the first die.

In further embodiments, the area corresponding to the I/O region is in the center of the preform film and the area outside the I/O region is peripheral to the center, bonding comprises thermal compression bonding, and the first die has a second I/O region outside the first I/O region, the method further comprising applying a unfilled NCP to the second I/O region.

Further embodiments include applying solder to the I/O region before applying the NCP and wherein bonding comprises reflowing the solder.

Some embodiments pertain to an apparatus including a first die having an I/O region, a second die bonded to the first die having an I/O region aligned with the corresponding I/O region of the first die, a first electrically-non-conductive underfill paste (NCP) type proximate the I/O region of the first and second die, and a second NCP type outside the VO region, the second NCP type having more filler than the first NCP type.

In further embodiments, the second NCP type has a filler loading of 75%. Further embodiments include solder bonds between the pads of the I/O region of the first and the second die. In further embodiments, the solder bonds are formed by thermal compression bonding.

Some embodiments pertain to a stacked die package including a package substrate, a cover over the package substrate, a first die coupled to the package substrate within the cover, the first die having an I/O region, a second die bonded to the first die within the cover, the second die having an I/O region aligned with the corresponding I/O region of the first die, a first electrically-non-conductive underfill paste (NCP) type proximate the I/O region of the first and second die, and a second NCP type outside the I/O region, the second NCP type having more filler than the first NCP type.

In some embodiments, the filler is silica, and the cover is a molding compound.

1. A method for connecting dies with electrically-non-conductive underfill paste (NCP), the method comprising:
applying a first electrically-non-conductive underfill paste (NCP) type to a first I/O region of a surface of a first die;
applying a second NCP type to a second region of the same surface of the first die, the second regions including a second the I/O region of the same surface of the first die, the second NCP type having more dielectric filler than the first NCP type; and
bonding the second die to a first die using the first and the second NCP so that the first I/O region and the second I/O regions are electrically connected to the second die.

2. The method of claim 1, wherein applying the first and the second NCP types comprises applying using a dispenser.

3. The method of claim 1, wherein applying the first and the second NCP types comprises placing a preform film including the first and second NCP types on the first die.

4. The method of claim 1, wherein the first I/O region and the second I/O region have connection pads and wherein the connection pads of the first I/O region are larger than the connection pads of the second I/O region.

5. The method of claim 4, wherein the connection pads of the first I/O region are Wide I/O pads.

6. The method of claim 1, wherein applying the first NCP type comprises covering the first I/O region with an NCP with zero filler loading.

7. The method of claim 6, wherein applying the second NCP type comprises covering the second region outside the I/O region with a filled NCP.

8. The method of claim 7, wherein the second type of NCP has a filler loading.

9. The method of claim 1, further comprising forming a preform film with unfilled NCP in the first I/O region and filled NCP in the second region and wherein applying the first and the second NCP type comprises placing the preform film at the top of the first die.

10. The method of claim 9, wherein the first I/O region is in the center of the preform film and the area outside the first I/O region is peripheral to the center.

11. The method of claim 1, wherein bonding comprises thermal compression bonding.

12. The method of claim 1, further comprising applying a filled NCP the second I/O region.

13. The method of claim 1, further comprising applying solder to the I/O region before applying the NCP and wherein bonding comprises reflowing the solder.

14. The method of claim 1, wherein the filler is silica.
